(19) United States
(12) Patent Application Publication
(10) Pub. No.: US 2019/0263505 A1
(43) Pub. Date: Aug. 29, 2019

(54) ACTUATABLE AIRCRAFT COMPONENT

(71) Applicant: AIRBUS OPERATIONS LIMITED, Bristol (GB)

(72) Inventor: Paul BLADES, Bristol (GB)

(21) Appl. No.: 16/346,345

(22) PCT Filed: Oct. 31, 2017
(86) PCT No.: PCT/EP2017/077853

§ 371 Date: Apr. 30, 2019

(30) Foreign Application Priority Data
Nov. 1, 2016 (GB) 1618393.1

(51) Int. Cl. B64C 23/00; B64C 9/02; B64C 9/18; H01L 41/09; H01L 41/193

(52) U.S. Cl. CPC B64C 23/005; B64C 9/02; B64C 2009/143; H01L 41/0926; H01L 41/193; B64C 9/18

(57) ABSTRACT

A method and system for actuating an aircraft component is disclosed including an actuating material in which an actual deformation change undergone by the actuating material in response to an activation input signal is determined by analysis of an output signal generated by the actuating material in response to the actual deformation. At least a portion of the aircraft component includes an actuating material which undergoes deformation in response to the application of an electrical signal thereto, and which generates an electrical signal in response to a deformation of the actuating material. The method includes applying an activation input signal to the actuating material of the aircraft component, the activation input signal corresponding to a desired deformation of the actuating material, the actuating material of the aircraft component undergoing an actual deformation in response to the activation input signal, and generating an output signal representative of the actual deformation of the actuating material.

### FIELD OF THE INVENTION

The present invention relates to actuation of aircraft components, and in particular to determining an actual deformation undergone by an actuated aircraft component.

### BACKGROUND OF THE INVENTION

Many aircraft components have essentially compromised designs which provide benefits in one or more flight phases, but which generate penalties (e.g. drag penalties) in other flight phases. In aircraft design it is necessary to balance the degree of compromise to ensure that the benefits outweigh the penalties. In practice this means that the design is often compromised in all flight phases.

### SUMMARY OF THE INVENTION

The present invention is concerned with actuating such aircraft components to tailor their configuration to achieve improved performance in one or more flight phases.

In general terms, the invention provides a method and system for actuating an aircraft component comprising an actuating material in which the actuating material generates an output signal in response to an actual deformation it undergoes, this output signal being representative of that actual deformation.

A first aspect of the invention provides a method of actuating an aircraft component, at least a portion of the aircraft component comprising an actuating material which undergoes deformation in response to the application of an electrical signal thereto, and which generates an electrical signal in response to a deformation of the actuating material, the method comprising the steps of: applying an activation input signal to the actuating material of the aircraft component, the activation input signal corresponding to a desired deformation of the actuating material, the actuating material of the aircraft component undergoing an actual deformation in response to the activation input signal; and generating an output signal representative of the actual deformation of the actuating material.

A second aspect of the invention provides an aircraft component actuating system for actuating an aircraft component, the system comprising: an aircraft component comprising an actuating material which is configured to deform in response to the application of an electrical signal thereto, and which is configured to generate an electrical signal in response to a deformation of the actuating material; a controller configured to transmit an activation input signal to the actuating material of the aircraft component corresponding to a desired deformation of the actuating material, and further configured to receive from the actuating material a generated output signal representative of an actual deformation of the actuating material.

The arrangement of the first and second aspect enables the configuration (i.e. shape or internal mechanical properties such as stiffness) of an aircraft component to be changed by simple application of the activation input signal. Moreover, the output signal generated by the actuating material in response to the deformation provides an indication of the nature of the actual deformation undergone. In this way the actuating material provides both an actuating function and a sensing function. The performance of the aircraft component (e.g. throughout each flight, the life of the component, or a test phase of the aircraft) can be determined using the actuating material, without the need for separate sensing devices. This provides a significant weight saving advantage, in addition to the increased ability for performance analysis.

The portion of the aircraft component comprising the actuating material may be bonded to, co-bonded with, or otherwise fixed to a substrate. Alternatively, the aircraft component may comprise a fibre-reinforced composite material, and the actuating material may comprise particles dispersed throughout the matrix of the composite material and/or may comprise a plurality of filaments extending through the matrix.

The actuating material may comprise an electro-active polymer, or any material which has piezoelectric properties such that it undergoes deformation in response to an electrical signal and produces an electrical signal in response to a deformation.

The actuating material may deform by expanding, contracting or in any other way. In some embodiments the application of the activation input signal may result in a change in stiffness of the actuating material.

The activation input signal is preferably actively controlled based upon the generated output signal, e.g. via closed-loop control. Thus, if the generated output signal indicates that the actual deformation is not within acceptable margins of the desired deformation then the activation input signal can be modified accordingly. For example, external forces applied to the aircraft component, such as aerodynamic forces, may influence the aircraft component such that the actuating material is unable to achieve the desired deformation. By monitoring the actual deformation via the output signal, the characteristics of the input activation signal can be controlled to counteract those external forces and achieve closer correspondence between the desired and actual deformations.

In some embodiments the activation input signal is controlled based upon an instruction from a flight control computer of the aircraft. The instruction from the flight control computer may itself be based on a control input from the cockpit (pilot control) or from a fly-by-wire (auto pilot) control input, or a monitoring input from a movable control surface.

In some embodiments the aircraft component is formed from a fibre-reinforced composite material, wherein the actuating material is embedded in the matrix of the composite material. The actuating material may comprise particles dispersed through the matrix, and/or filaments embedded in the matrix. Such filaments may be interwoven with reinforcing fibres of the composite material. By embedding the actuating material in the matrix in this way the number of fabrication steps is reduced, and the risk of delamination or debonding of is minimised. Alternatively, the actuating material may be co-bonded or co-cured with a substrate to form a composite material.

The aircraft component may be located upon an aerodynamic surface of the aircraft. For example, the aircraft component may comprise one of the following components: a rain gutter; a vortex generator; a NACA duct; a fuel system access component. Such components provide benefits at one or more flight phases (or on the ground), and penalties at one or more other flight phases. Thus, controlling the configuration of such components to maximise the benefits and minimise the penalties can be very advantageous.

In preferred embodiments the desired deformation serves to alter an air gap between the aircraft component and a movable control surface configured to be movable between a stowed configuration and a deployed configuration. Such gap control can be used to manage flow separation during different flight phases. For example, a convergent gap which narrows in the direction of airflow may be especially desirable in some embodiments. In particular, the movable control surface may comprise a trailing edge flap and the desired deformation may alter the air gap to provide a convergent gap between the aircraft component and the flap in the deployed configuration of the flap. The aircraft component may comprise an actuatable trailing edge portion extending from a trailing edge of a spoiler or fixed wing panel.

In other embodiments the aircraft component is a seal located between first and second surfaces, the second surface comprising a moveable control surface configured to move between a stowed configuration and a deployed configuration, wherein the desired deformation of the seal tends to urge the seal in a first direction towards the second surface.

Thus, the seal can be urged into contact with the movable control surface during cruise, in order to provide an aerodynamically beneficial profile and avoid undesirable flutter. Any such flutter, or other unfavourable aerodynamic profiles, can be diagnosed by analysis of the output signal. Moreover, the shape, contour and/or stiffness of the seal along its length can be varied in accordance with the aerodynamic requirements and/or the seal's performance.

Such embodiments preferably comprise the further steps of: applying a second activation input signal to the actuating material of the seal, the second activation input signal corresponding to a second desired deformation of the seal tending to urge the seal in a second direction opposite to the first direction, the actuating material of the seal undergoing a second actual deformation in response to the second activation input signal; and generating a second output signal representative of the second actual displacement of the actuating material of the seal.

Thus, the seal may be deflected away from the movable control surface during deployment thereof in order to avoid entrapment of the seal by the movable control surface.

In preferred seal embodiments the first or second activation input signal is applied to the actuating material of the seal in response to the movement of the second surface between the stowed configuration and deployed configuration.

The aircraft component may project from a moveable control surface, and the desired deformation of the actuating material may provide movement of the aircraft component relative to the movable control surface. Thus the aircraft component may be actuatable to provide an additional degree of control to the lift or drag influencing characteristics of the movable control surface. For example, the aircraft component may be actuatable to vary the curvature of the upper aerodynamic profile provided by the movable control surface. Such an arrangement can provide a continuously adaptable flight control surface. Moreover, by analysing the output signal it is possible to provide load alleviation and buffet reduction for reduced wing loading and/or passenger comfort.

In preferred embodiments the moveable control surface comprises a trailing edge flap configured to move between a stowed configuration and a deployed configuration, and the aircraft component projects from a trailing edge of the flap. This arrangement provides a tabbed flap which can provide a flap with a variable camber in high-lift flight phases, without adding a significant drag penalty during cruise.

In some embodiments the desired deformation and the actual deformation comprise a desired shape change and an actual shape change, respectively. That is, the deformation results in a change of shape (geometry) of the actuating material.

In other embodiments the desired deformation and the actual deformation comprise a desired generation of mechanical stress and an actual generation of mechanical stress, respectively. Thus, the deformation results in a change to the internal form/configuration of the actuating material in which internally generated forces result in a mechanical stress. This stress may result in a shape change of the actuating material (as a result of the induced strain) or a change in mechanical properties such as stiffness.

A third aspect of the invention provides an aircraft comprising the system of the second aspect.

Any of the features of the invention described herein as optional or desirable may be applied to any aspect of the invention, either individually or in any combination.

### BRIEF DESCRIPTION OF THE DRAWINGS

Embodiments of the invention will now be described with reference to the accompanying drawings, in which:

FIGS. 1A-C illustrate an aircraft component actuating system comprising an electro-active polymer actuating material in a neutral (unstimulated) configuration (FIG. 1A), a first configuration (FIG. 1B), and a second configuration (FIG. 1C);

FIG. 2 is a schematic of an aircraft component actuating system according to an embodiment of the invention;

FIGS. 3A and 3B are isometric views of an aircraft;

FIGS. 4A-C are schematic side section views of an actuatable seal according to an embodiment of the invention during a cruise phase (FIG. 4A), a high-lift phase (FIG. 4B), and a maintenance condition (FIG. 4C);

FIGS. 5A and 5B are schematic side section views of a trailing edge assembly with an actuatable trailing edge device shown in a cruise configuration (FIG. 5A) and a high-lift configuration (FIG. 5B);

FIGS. 6A and 6B are schematic section views illustrating the actuatable trailing edge device of the embodiment of FIGS. 5A and 5B;

FIGS. 7A-F are schematic views illustrating an actuatable rain gutter according to embodiments of the invention; and

FIG. 8 shows an actuatable vortex generator according to an embodiment of the invention.

### DETAILED DESCRIPTION OF EMBODIMENT(S)

Electro-active polymers are polymers that undergo a deformation, i.e. change in shape and/or internal mechanical stresses/stiffness, when stimulated by an electrical field. Thus, application of an electrical signal to an electro-active polymer causes the electro-active polymer to undergo a deformation. The electrical signal is representative of the desired deformation to be achieved by the electro-active polymer. In this way, characteristics of the electrical signal can be controlled to achieve desired characteristics of the deformation.

Moreover, electro-active polymers can also provide an inverse response; that is, an electro-active polymer will generate an electrical signal in response to an actual deformation of the electro-active polymer. The generated electrical signal is representative of the actual deformation, such that characteristics of the signal can be interpreted to determine characteristics of the deformation.

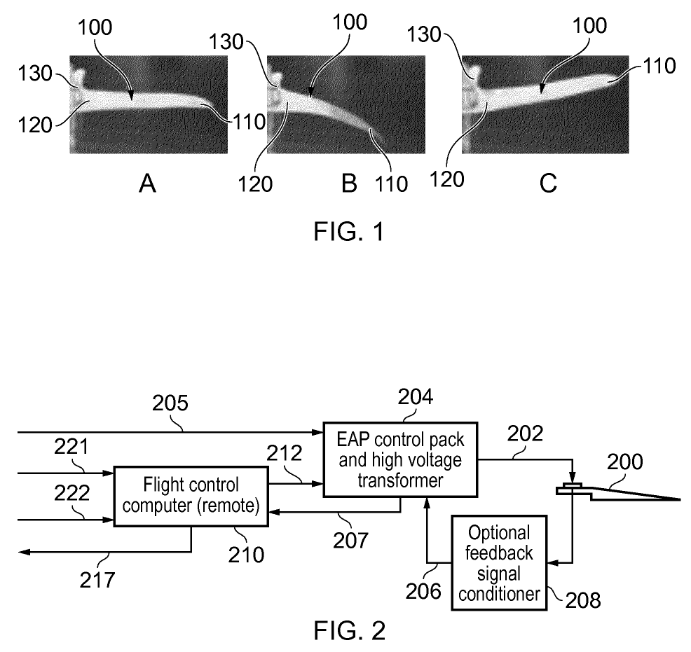

FIGS. 1A-1C show an illustrative aircraft component actuating system comprising an aircraft component 100 fixed at a root end 120 by a clamp 130 and free at a tip end 110. The aircraft component 100 consists of an electro-active polymer actuating material which is in electrical communication with a signal generator (not shown). In other embodiments the aircraft component 100 may include one or more portions comprising the actuating material, and one or more portions comprising other materials. The signal generator is configured to apply an electrical signal to the actuating material 100. A signal recording device (not shown) is configured to receive an electrical signal generated by the actuating material 100.

In the absence of an electrical signal applied to it, the unstimulated actuating material of the aircraft component 100 remains in a neutral position as shown in FIG. 1A. In the neutral position the aircraft component is typically substantially straight such that its tip 110 has not undergone a vertical displacement relative to its root 120.

FIG. 1B illustrates a deformation of the aircraft component in response to stimulation by input of a first activation input signal via the signal generator. Upon the application of the first activation input signal, the stimulated actuating material of the aircraft component 100 undergoes a first deformation in which the tip 110 is displaced in a first direction (downwardly, in FIG. 1B) relative to the root 120. As can be observed in FIG. 1B, the actuating material of the aircraft component 100 in the first deformation (stimulated) position is no longer substantially straight and instead defines an arcuate profile in which the tip 110 has undergone a negative vertical displacement relative to the root 120. Upon the removal of the first activation input signal, the unstimulated actuating material of the aircraft component 100 returns to the neutral position, as illustrated in FIG. 1A.

FIG. 1C illustrates a deformation of the aircraft component in response to stimulation by input of a second activation input signal via the signal generator. Upon the application of the second activation input signal, the stimulated actuating material of the aircraft component 100 undergoes a second deformation in which the tip 110 is displaced in a second direction (upwardly, in FIG. 1C), opposite to the first direction, relative to the root 120. As can be observed in FIG. 1C, the actuating material of the aircraft component 100 in the second deformation (stimulated) position is no longer substantially straight and instead defines an arcuate profile in which the tip 110 has undergone a positive vertical displacement relative to the root 120. Upon the removal of the second activation input signal, the unstimulated actuating material of the aircraft component 100 returns to the neutral position, as illustrated in FIG. 1A.

The second deformation position (FIG. 1C) is not a mirror image of the first deformation position (FIG. 1B), though it may be so in some embodiments. Thus, it is possible to achieve different shape configurations of the actuating material of the aircraft component 100 by applying different activation input signals. For example, a position intermediate the first and second deformation positions may be desirable.

Thus, the electro-active polymer system of FIGS. 1A-1C provides an aircraft component 100 which can be moved from a neutral position (FIG. 1A) to either a first deformation position (FIG. 1B) or a second deformation position (FIG. 1B).

In other embodiments the aircraft component 100 may not undergo a shape change, but may instead undergo another type of deformation, such as internal configuration change caused by a change in internal mechanical stresses leading to a change in mechanical stiffness.

FIG. 2 illustrates an actuating control system suitable for controlling the deformation of the aircraft component 100 of FIGS. 1A-1C.

The control system comprises an aircraft component which includes an actuating material element 200 in electrical communication with a controller 204. The element 200 is formed from an actuating material, which in this embodiment is an electro-active polymer. The controller is configured to apply an activation input signal 202 to the actuating material element 200. The activation input signal 202 corresponds to the desired deformation that the actuating material element 200 is intended to undergo.

In the embodiment of FIG. 2, the activation input signal 202 applied to the actuating material element 200 can be varied by the controller 204 based upon a control signal 212 applied to the controller 204 by a flight control computer 210. The control signal 212 output by the flight control computer 210 may be varied based upon signals input to the flight control computer, such a pilot or fly-by-wire control input 221, an input from flight control or monitoring inputs 222 or a combination of the two in addition to any other signal input to the flight control computer 210. In alternative embodiments, the controller 204 may be pre-programmed with a non-variable activation input signal 202 which is not changed in response to instructions from the flight control computer 210.

In the embodiment of FIG. 2 the controller 204 is connected to a power supply 205 which provides the controller with electrical power. The power supply may be an internal power supply within the controller 204, may be drawn from the aircraft power supply or may comprise any other power supply configuration. In the case where the power supply is a low voltage power supply, the controller 204 may also require a transformer (not shown) to condition the low voltage power supply into a high voltage power supply, suitable for application to the electro-active polymer element 200. In the illustrated described in FIG. 2, the power supply 205 is drawn from the aircraft power supply.

The controller 204 is also configured to receive an output signal 206 generated by the actuating material of the element 200 in response to the actual deformation undergone by the actuating material. The actual deformation may differ to the desired deformation of the actuating material due to external forces acting upon the actuating material element 200 in addition to the actuating force. That is, the magnitude and/or direction of the actual deformation may be different from the intended desired deformation such that the actual deformation of the actuating material element 200 is not exactly as intended. Such external forces may be caused, for example, by the effects of resonant frequencies and component flutter during differing flight phases of the aircraft. The output signal 206 thus provides a signal that is representative of the actual deformation experienced by the actuating material of the element 200.

In open-loop control embodiments the output signal is not fed back to the controller 204. However, in the closed-loop control embodiment of FIG. 2 the output signal is fed into a signal conditioner 208 before being fed back into the controller 204. In an alternate embodiment the signal conditioner 208 may be omitted.

By feeding the output signal 206 back to the controller 204, the activation input signal 202—which corresponds to the desired deformation—may be actively controlled based upon the output signal 206, i.e. via closed-loop control. That is, if the output signal 206 indicates that the actual deformation of the actuating material element 200 is not within given tolerance boundaries of the intended desired deformation, then the activation input signal 202 may be adjusted accordingly.

This control feedback loop ensures that the actual deformation of the actuating material element 200 is within acceptable margins of the desired deformation, and allows external forces acting upon the actuating material element 200 to be compensated for. Such active control may be carried out in real time during flight of the aircraft, or may be carried out at discrete intervals during routine maintenance of the aircraft or during a flight test programme.

Signals and/or data from the controller 204 may also be fed back to the flight control computer 210 via controller feedback signal 207, and signals and/or data from the flight control computer may also be fed back to the pilot or fly-by-wire system by computer feedback signal 217. Thus, the flight control computer 210 may determine whether or not to adjust the activation input signal 202 based on the output signal 206.

The arrangement described above in relation to FIGS. 1 and 2 provides an aircraft component whose deformation (which includes all geometric properties and internal mechanical properties, and which may have a direct influence on stiffness) can be configured for different flight phases. This enables the design of an aircraft component that can provide the optimum profile/stiffness for each flight control configuration and phase of flight, rather than the best compromise over the whole range of conditions.

This control can be directly integrated into a fly-by-wire aircraft, with the possibility of a continually variable profile which can be tunable as flight test data becomes available during early flights, or even at later stages of the aircrafts life where modifications to the aerodynamic performance of the wings, e.g. by changes to the movable control surfaces, can be accommodated by changes to the software controlling the aircraft component rather than by replacing the aircraft component.

Moreover, by taking advantage of the actuating materials ability to generate an electrical signal in response to a change in deformation, it is possible to provide positive feedback to identify and counteract undesirable behaviour of the aircraft component, such as resonant frequencies or other transient behaviours experienced by the aircraft component during a particular flight phase. Such unwanted behaviour can be identified by analysis of the generated output signal, and counteracted by modification of the activation input signal.

The arrangement illustrated in FIG. 2 is applicable to all embodiments of the invention, and in particular to each of the embodiments described in more detail below.

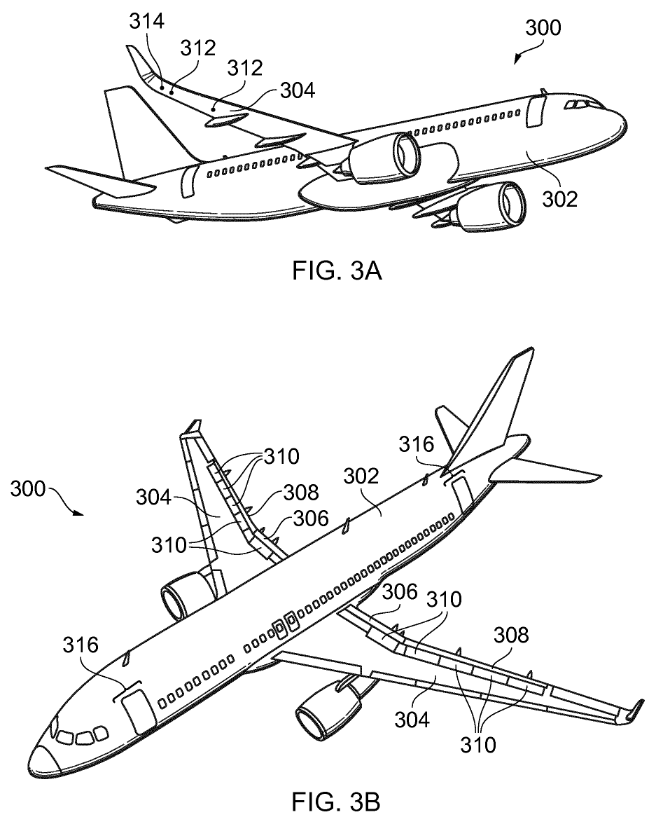

FIGS. 3A and 3B show oblique isometric views of an aircraft 300 from below and above, respectively. The aircraft comprises a fuselage 302 and a pair of wings 304. Each wing 304 comprises movable control surfaces including inboard 306 and outboard 308 flaps at the wing trailing edges, and a plurality of spoilers 310 (air brakes). The flaps 306, 308 comprise high lift devices which are deployed during take-off, approach and landing, and the spoilers 310 comprise lift reduction devices which are deployed during descent and landing. The invention can be embodied in improvements to such movable control surfaces, as discussed further below.

The aircraft also comprises vortex generators 312 which serve to delay flow separation over the wing 304. The illustrated vortex generators 312 are shown on the wing lower surface, upstream of fuel tank air vents. Vortex generators may alternatively be located elsewhere on the aircraft, including on the upper wing surface. The aircraft further comprises NACA ducts 314, which provide air flow inlets, and rain gutters 316 which extend over the top of each aircraft door to divert rain flow over the fuselage 302 from passengers using the doors. Such aircraft components have in common the fact that they perform a useful function in a particular flight phase or on the ground, while providing a drag penalty in other flight phases. The invention can be embodied in improvements to such aircraft components to address this issue, as discussed further below.

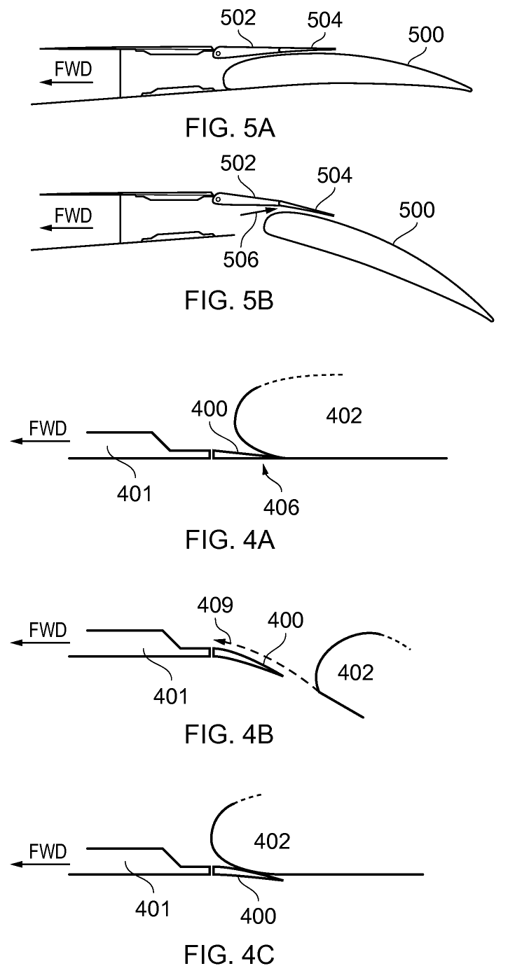

FIGS. 4A-C schematically illustrate an aircraft component comprising a blade seal 400 between a first surface 401 and a second surface 402. The blade seal 400 is a monolithic seal formed from an actuating material such as an electro-active polymer. In the embodiment of FIG. 4 the first surface 401 is a fixed lower wing panel. However, the first surface 401 may alternatively be a moveable control surface or any other suitable fixed surface. The second surface may typically be a moveable control surface, such as a flap.

When the aircraft is at cruise (FIG. 4A), a first activation input signal is provided to the actuating material of the blade seal 400, causing it to deform to adopt a first configuration (shape) in which its free end is displaced in a first direction towards the second surface 402 so that the blade seal 400 is urged into contact with the second surface 402. As shown in FIG. 4A, the seal 400 thus applies a preload force 406 to the second surface 402. The preload force 406 has the effect of creating a tight sealing arrangement against the second surfaces 401,402 which achieves an aerodynamic profile optimised for low drag. In the case where the second surface is a wing flap, the preload 406 also has the effect of preventing a loss of pressure between the upper and lower wing surfaces.

Referring to FIG. 4B, during flight phases which require high lift, the second surface 402 is required to move to a deployed configuration. During deployment, and subsequent retraction, of the second surface 402, the configuration (shape) of the blade seal 400 is changed so it deforms to adopt a second configuration (shape) in which there is no risk of entrapment of the blade seal 400. To achieve this the actuating material of the blade seal 400 is provided with a second input activation signal (different to the first activation input signal), which causes its free end to displace in a second direction opposite to the first direction. Typically this second direction is in a direction away from the second surface 402 which is being moved. The second input activation signal may also act to increase the stiffness of the seal during the deployment and retraction phases.

By actuating the blade seal 400 away from the second surface 402 whilst the second surface 402 is in motion, the possibility of the seal 400 becoming entrapped between the first and second surfaces is minimised. This is beneficial since an entrapped seal has an adverse effect upon the aerodynamic profile of the component and also would require a maintenance stop to be scheduled to rectify the problem. After the second surface 402 has been fully actuated into its high lift configuration, the seal may be further actuated to achieve an aerodynamically favourable profile in the high lift configuration (not shown). This may be achieved by creating a lip, a convergent gap, a divergent gap or any other favourable configuration that is capable of influencing flow separation and laminar flow.

FIG. 4C illustrates an on-ground maintenance configuration in which the second surface 402 is required to move outside of its normal operating envelope. In this configuration the seal 400 may be actuated to adopt a maintenance configuration in which the seal will not be entrapped or otherwise damaged by movement of the second surface 402. This maintenance configuration may correspond to a neutral configuration of the seal 400, i.e. the seal shape when no activation input signal is applied to it. Alternatively, a further input activation signal may be applied to the seal to achieve the maintenance configuration.

The blade seal 400 of FIG. 4 is controlled as per the control system described above with respect to FIG. 2. Thus, an output signal (206 in FIG. 2) is generated by the actuating material of the seal 400 in response to an actual deformation of the seal, the output signal being representative of that actual deformation. The activation input signal (202 in FIG. 2) can then be actively controlled based on the output signal.

In the embodiment of FIG. 4, the blade seal 400 is a monolithic seal made entirely from an electro-active polymer (or other actuating material). However, in an alternative embodiment the component may comprise strips or panels of electro-active polymer on the body of a non-electro-active substrate. In yet further embodiments the component may comprise a fibre-reinforced composite component in which fibres are distributed within a matrix, and the electro-active polymer may be distributed through the matrix of the composite component. Thus, the blade seal 400 may comprise a composite material in which only one or more portions of the composite material are formed from the electro-active polymer actuating material. For example, the actuating material may comprise a component part of a seal primarily formed from an elastomeric material such as a silicone rubber; such a seal may also include one or more fabric layers such as polyester fabric layers for stiffening and wear resistant surface facings, and/or glass/carbon fibre fabrics for structural strength.

FIGS. 5A and 5B schematically illustrates a wing trailing edge assembly in a cruise configuration (FIG. 5A) in which a trailing edge flap 500 is retracted, and a high lift configuration (FIG. 5B) in which the flap 500 is deployed. A spoiler 502 (air brake) is movable between a low lift configuration (not shown) in which it is hinged about its forward end, and the illustrated stowed configuration. An actuatable trailing edge device 504 is fixed at one end thereof to an aft edge of the spoiler and extends rearwardly over the flap.

The actuatable trailing edge device 504 comprises an actuating material such as an electro-active polymer. In response to deployment of the flap 500, the actuatable trailing edge device 504 is actuated by application of a first activation input signal to induce a first deformation to a first configuration (shape) which provides a downward curvature as shown in FIG. 5B. The first configuration (shape) of the actuatable trailing edge device 504 is such that it forms a convergent gap with the flap 500 such that a gap, or slot, between the deployed flap 500 and the actuatable trailing edge device 504 becomes progressively narrower in the direction of an air flow 506 through the gap. Such a convergent gap is known to provide desirable airflow characteristics in some high-lift conditions.

It is also desirable that the actuatable trailing edge device 504 have a high stiffness when it is in the first configuration, to ensure that the convergent gap is maintained within acceptable tolerances. Thus, the first activation input signal induces an increase in stiffness of the activating material, in tandem with the shape change.

During non high-lift flight phases, especially cruise, it is desirable for the actuatable trailing edge device 504 to adopt a shape in which it provides the aerodynamic profile with the lowest drag penalty. Thus, in response to retraction of the flap 500, the actuatable trailing edge device 504 is actuated to induce a second deformation to a second shape which provides such an aerodynamic shape, as illustrated in FIG. 5A. This second shape may correspond to the neutral configuration of the actuating material, and may therefore be induced by ceasing application of the first activation input signal. Alternatively, the second shape may be induced by applying a second activation input signal, different to the first activation input signal, to the actuating material.

As described above in relation to other embodiments, the actual deformation achieved by application of the first and/or second input activation signals will typically not exactly correspond to the desired deformation. The actual deformation achieved is determined by analysis of an output signal generated by the actuating material in response to the actual deformation, via the methods described above (and in particular as illustrated in FIG. 2). Further, the actual deformation may be controlled by active (closed-loop) control of the first and/or second activation input signals as described above (and in particular as illustrated in FIG. 2).

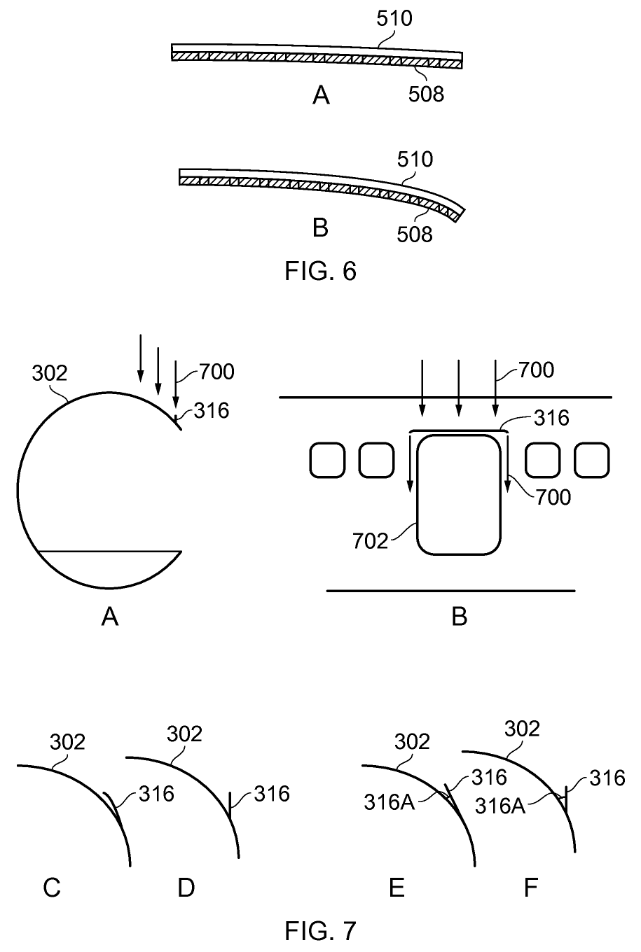

In some embodiments the actuatable trailing edge device will be monolithically formed from the actuating material, and in others it will comprise one or more portions of actuating material. For example, as illustrated in FIGS. 6A and 6B, a layer 508 of actuating material may be bonded to a lower surface of a metallic or composite panel 510. In such embodiments the strain induced in the panel 510 by a reduction in length of the actuating material layer 508 on application of an activation input signal induces shear in the panel 510 to induce the desired deflection. In yet further embodiments the actuatable trailing edge device may comprise a fibre-reinforced composite component in which fibres are distributed within a matrix, and the electro-active polymer may be distributed into the matrix of composite component.

Although in the embodiment of FIG. 5 the actuatable trailing edge portion 504 extends from the aft edge of a deployable spoiler 502, in other embodiments the actuatable trailing edge portion 504 may extend from the aft edge of a fixed wing portion such as a fixed panel of a wing trailing edge assembly or a shroud box assembly.

In yet further embodiments the actuatable trailing edge portion 504 may alternatively extend from the aft edge of another movable control surface, such as a trailing edge flap. In such embodiments the actuatable trailing edge portion provides a flap tab that extends along the aft edge of the flap and is actuatable relative to the flap. The tab can be fixed at one end to the flap so that actuation of the actuating material of the tab causes its free end to move relative to its fixed end. In this way, the tab can be actuated so that its free end moves downwardly relative to the flap, to increase the curvature of the flap and therefore increase lift in the deployed high lift configuration of the flap.

FIGS. 7E-F schematically illustrate an actuatable rain gutter 316 (also shown in FIGS. 3A-B). FIGS. 7A and 7B illustrate the role of the rain gutter 316 in preventing rain 700 falling on the fuselage 302 from dripping onto passengers passing through an aircraft door 702. In embodiments of the invention the rain gutter 316 may be formed either entirely or partially from an actuating material and controlled in accordance with the invention as described herein to be retracted (FIG. 7C) during flight to reduce parasitic drag, and deployed (FIG. 7D) when the aircraft is on the ground. In other embodiments of the invention the rain gutter 316 may include an actuator portion 316A extending between the fuselage 302 and the rain gutter 316, the actuator portion 316 being extendable in length to urge the rain gutter 316 away from the fuselage 302 to its deployed configuration. In both such embodiments the neutral configuration of the actuating material preferably achieves retraction of the rain gutter, so that power need be applied only when actuation of the rain gutter to its deployed state is required.

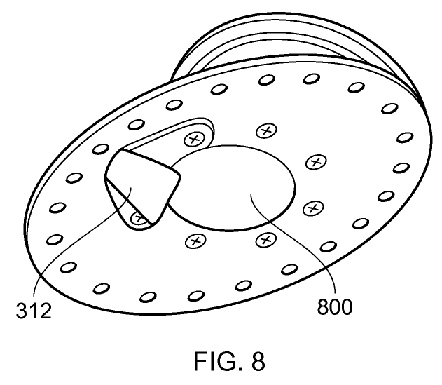

FIG. 8 illustrates an example of a vortex generator 312 (identified in FIG. 3A) which may be actuatable in accordance with the present invention. The vortex generator 312 is provided on the aerodynamic surface, upstream of a fuel over pressure protection (FOPP) cavity 800 to reduce the noise generated by the FOPP cavity 800 during landing approach. In embodiments of the invention the vortex generator 312 may be formed wholly or in part from an actuating material controlled in accordance with the methods described herein in order to change the shape of the vortex generator. For example, the shape may be changed to vary the projection height (i.e. distance of projection from the aerodynamic surface) or profile of the vortex generator. The shape may be changed for each flight phase to optimise performance, and/or may be varied continuously to provide the optimum aerodynamic profile.

Although the invention has been described above with reference to one or more preferred embodiments, it will be appreciated that various changes or modifications may be made without departing from the scope of the invention as defined in the appended claims.

In particular, the embodiments described above utilise electro-active polymers to achieve the required displacement of the aircraft component, but in other embodiments other suitable materials, such as materials having piezoelectric properties, may be used instead.

In all of the embodiments described herein the aircraft component may be formed monolithically from the actuating material, such as an electro-active polymer, or may comprise a composite component in which one or more portions comprise the actuating material.

Alternatively, the aircraft component may comprise a fibre-reinforced composite material in which reinforcing fibres are embedded in a matrix. In such embodiments the actuating material may be dispersed as particles throughout the matrix, providing the benefit of reducing additional fabrication steps and reducing delamination/debonding risks. The actuating material/matrix fraction would need to be tailored to ensure the actuating material content is sufficiently high to deliver the required mechanical force without compromising the load carrying ability of the composite matrix, or increasing its mass/dimensions beyond acceptable limits. This is considered most likely to be an attractive option for structures that take advantage of the expansion of the actuating material to drive the deformation.

As another alternative for embodiments in which the aircraft component comprises a fibre-reinforced composite material, the actuating material may be incorporated in filament form into the fibre weave of the composite material. By varying the location within the matrix (e.g. above or below the neutral axis, or parallel to the ±45° weave) it is possible to design a composite structure that has the ability to be deformed in both the x, y, and a axes (i.e. in plane and out of plane) by inducing strain in the appropriate plane. Careful choice of materials is necessary in order to limit the charge dissipation of the actuating material filaments into the composite matrix when the resistivity of the matrix is such that it ‘bleeds’ charge away from the actuating material. This may be achieved by resistive coatings applied to the actuating material, analogous to those used in electric transformer and motor windings to prevent short circuits. Moreover, tailoring the bulk of the actuating material fibres in the desired direction enables the material to apply a greater force in the desired plane, or exhibit varying degrees of deflection capability; it also enables the tailoring of the stiffness/strength of the composite structure by altering the fibre/actuating material ratio in the desired plane.

1. A method of actuating an aircraft component, at least a portion of the aircraft component comprising an actuating material which undergoes deformation in response to the application of an electrical signal thereto, and which generates an electrical signal in response to a deformation of the actuating material, the method comprising the steps of:
a. applying an activation input signal to the actuating material of the aircraft component, the activation input signal corresponding to a desired deformation of the actuating material, the actuating material of the aircraft component undergoing an actual deformation in response to the activation input signal; and
b. generating an output signal representative of the actual deformation of the actuating material.

2. The method of claim 1 further comprising the step of actively controlling the activation input signal based upon the generated output signal.

3. The method of claim 1, further comprising the step of modifying the activation input signal based upon an instruction from a flight control computer of the aircraft.

4. (canceled)

5. (canceled)

6. The method of claim 1 wherein the aircraft component is located upon an aerodynamic surface of the aircraft.

7. The method of claim 1, wherein the desired deformation serves to alter an air gap between the aircraft component and a movable control surface configured to be movable between a stowed configuration and a deployed configuration.

8. The method of claim 10, wherein the movable control surface comprises a trailing edge flap and the desired deformation alters the air gap to provide a convergent gap between the aircraft component and the flap in the deployed configuration of the flap.

9. The method of claim 1, wherein the aircraft component is a seal located between first and second surfaces, the second surface comprising a moveable control surface configured to move between a stowed configuration and a deployed configuration, wherein in step (a) the desired deformation of the seal tends to urge the seal in a first direction towards the second surface.

10. The method of claim 9, comprising the further steps of:
c. applying a second activation input signal to the actuating material of the seal, the second activation input signal corresponding to a second desired deformation of the seal tending to urge the seal in a second direction opposite to the first direction, the actuating material of the seal undergoing a second actual deformation in response to the second activation input signal; and
d. generating a second output signal representative of the second actual deformation of the actuating material of the seal.

11. The method of claim 9, comprising the further step of applying the first or second activation input signal to the actuating material of the seal in response to the movement of the second surface between the stowed configuration and deployed configuration.

12. The method of claim 1 wherein the aircraft component projects from a moveable control surface, and the desired deformation of the actuating material provides movement of the aircraft component relative to the movable control surface.

13. The method of claim 12 wherein the moveable control surface comprises a trailing edge flap configured to move between a stowed configuration and a deployed configuration, and the aircraft component projects from a trailing edge of the flap.

14. (canceled)

15. The method of claim 1, wherein the desired deformation and the actual deformation comprise a desired shape change and an actual shape change, respectively.

16. The method of claim 1, wherein the desired deformation and the actual deformation comprise a desired generation of mechanical stress and an actual generation of mechanical stress, respectively.

17. An aircraft component actuating system for actuating an aircraft component, the system comprising:
an aircraft component comprising an actuating material which is configured to change shape in response to the application of an electrical signal thereto, and which is configured to generate an electrical signal in response to a deformation of the actuating material;
a controller configured to transmit an activation input signal to the actuating material of the aircraft component corresponding to a desired deformation of the actuating material, and further configured to receive from the actuating material a generated output signal representative of an actual deformation of the actuating material.

18. The system of claim 17, wherein the controller is further configured to actively control the activation input signal based upon the generated output signal.

19. The system of claim 17, further comprising a flight control computer configured to apply a desired control input signal to the controller, and wherein the controller is further configured to modify the activation input signal based upon the desired control input signal.

20. The system of claim 17, wherein the actuating material comprises an electro-active polymer.

21. The system of claim 17, wherein the aircraft component is formed from a fibre-reinforced composite material, wherein the actuating material is embedded in the matrix of the composite material.

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. The method of claim 1, wherein the deformation comprises either a shape change or an internal configurational change resulting in mechanical stress of the actuating material.

34. The system of claim 17, wherein the deformation comprises either a shape change or an internal configurational change resulting in mechanical stress of the actuating material.
